(19) United States
(12) Patent Application Publication
(10) Pub. No.: US 2025/0079546 A1
(43) Pub. Date: Mar. 6, 2025

(54) Direct Upcycling of Lithium-ion Battery Cathodes to Single-Crystal Nickel-rich NCMs

(71) Applicant: THE REGENTS OF THE UNIVERSITY OF CALIFORNIA, Oakland, CA (US)

(72) Inventors: Zheng CHEN, San Diego, CA (US); Hongpeng GAO, La Jolla, CA (US)

(21) Appl. No.: 18/827,422

(22) Filed: Sep. 6, 2024

Related U.S. Application Data
(60) Provisional application No. 63/536,890, filed on Sep. 6, 2023.

(51) Int. Cl. H01M 10/54; C30B 9/00; C30B 29/26

(52) U.S. Cl. CPC H01M 10/54; C30B 9/00; C30B 29/26

(57) ABSTRACT

The present disclosure relates to methods for upcycling of spent lithium-ion battery cathodes. In some embodiments, the methods may include admixing delithiated NCM particles with a supplementary lithium source comprising a single lithium salt to produce single-crystal NCM particles with effective size control and improved electrochemical performance compared to pristine polycrystalline NCM.

### RELATED APPLICATIONS

This application claims the benefit of the priority of U.S. Provisional Application No. 63/536,890, filed Sep. 6, 2023, which is incorporated herein by reference in its entirety.

### GOVERNMENT RIGHTS

This invention was made with government support under Grant No. DE-AC02-06CH-11357 awarded by the Department of Energy. The government has certain rights in the invention.

### FIELD

The present invention relates to recycling, recovery, and regeneration of materials from spent lithium-ion batteries.

### BACKGROUND

Rapid growth in lithium-ion battery (LIB) production has served the rising demand for portable electronics, electric vehicles (EVs), and grid energy storage systems. Since the 2010s, the rapid growth of EVs has been accompanied by tumbling prices and enormous enthusiasm for LIBs. As these EVs inevitably reach their end of life (EOL)—typically 8-10 years—many spent LIBs will be created. For these EOL batteries, which may still possess up to 80% of their original capacity, one potential solution is to reuse them in less demanding applications, such as utility and backup power storage devices, where their useful lifespan can be extended. Even so, this approach only postpones the eventual requirement for recycling. It remains a critical and pressing issue to recycle all EOL LIBs.

Hydrometallurgical and pyrometallurgical processes have been adopted in the state-of-the-art LIB recycling industry. Such processes involve intensive energy consumption and caustic materials, including high-temperature smelting, acid leaching, and chemical precipitation, which are inevitably associated with heavy CO₂ emission and other waste generation. On the other hand, the emerging direct recycling technology has attracted rising attention due to the minimum energy consumption and maximum potential profit compared with traditional hydrometallurgical and pyrometallurgical recycling methods. Efforts have been focused on healing the structure and composition defects of cathode active materials from spent LIBs, including solid-state sintering, hydrothermal treatment, ionothermal, redox mediation¹⁵, and molten eutectic salt relithiation followed by a short annealing process. While solid-state sintering by mixing all precursors in a stoichiometric ratio appears on its face to be a simple strategy, determining the amount of supplementary Li source is challenging for the mixed waste streams with spent LIBs having a wide range of state of health (SOH). By comparison, some self-saturated relithiation strategies have demonstrated high effectiveness in direct recycling without considering the SOH variation.

Given the growing demands in high energy density LIBs, improving the performance of spent cathode active materials beyond the original pristine materials via recycling processes remains challenging as a critical milestone in the next-generation battery recycling. In addition, single-crystal LiNiₓCo_{y}Mn_{1-x-y}O₂ (NCM) cathodes have attracted increasing attention due to their superior structural stability compared with conventional polycrystalline particles. As the polycrystalline particles are susceptible to accumulation of lattice strain and lattice distortion due to the grain boundary evolution, an effective direct approach to eliminate grain boundary fracture is to convert polycrystalline into single-crystal domains, delivering superior kinetics and rate capability with significant integrity improvement with optimized size and morphology control. Recently, a molten salt method based on LiOH—Li₂SO₄ salt mixture has been demonstrated to upgrade polycrystalline NCM 111 and NCM 532 into single-crystal NCM 622. This concept has also been illustrated to convert spent polycrystal LiNi_{0.88}Co_{0.095}Al_{0.025}O₂(NCA) into regenerated single-crystal with same composition by LiOH—Na₂SO₄ eutectic molten salt system. Moreover, a reciprocal ternary molten salt system of LiNO₃—NaCl has been developed for upcycling spent NCM 111 into NCM 622. At the same time, producing high-performance nickel-rich cathodes (Ni>80%) has garnered significant attention due to their high energy output. In this regard, upgrading spent NCM 111 into single-crystal NCM 811 (or even higher Ni) is being considered as one of the ultimate solutions to avoid the multi-step high-temperature calcination process by using excess lithium salt or a molten-salt flux method. Nonetheless, upcycling low-nickel cathodes to NCM 811 remains a difficult task. Accordingly, the need remains for sustainable end-of-life battery management to reduce greenhouse emissions and resource consumption to make a low-carbon future.

### SUMMARY

The inventive approach relates to a method for upgrading polycrystalline delithiated NCM 111 (D-NCM 111) into single-crystal NCM 811 with LiOH as a single supplementary source of lithium. This approach is also effective in synthesizing single-crystal NCM 433 and 622 through the tuning of the precursor ratios. Ostwald ripening phenomenon, occurring during flux growth of oxides when merging D-NCM with Ni precursor, was found to play a dominant role in determining particle morphology. Uniformity of Ni valence and distribution in upcycled single-crystal NMC were evaluated and found to exhibit outstanding electrochemical performance as compared to their polycrystalline counterparts. Particularly, the resulting upcycled NCM 811 exhibited a significant improvement of its rate capability with good cycling stability, surpassing the performance of the original polycrystalline NCM 811. This effective direct upcycling method with limited Li salt, avoiding excess molten salt flux, significantly reduces the overall cost as well as simplifying the recycling process, providing a feasible pathway to scalable direct upcycling.

The inventive upcycling method provides for efficient conversion of spent polycrystalline LiNi_{0.33}Co_{0.33}Mn_{0.33}O₂(NCM 111) up to single-crystal LiNi_{0.8}Co_{0.1}Mn_{0.1}O₂ (NCM 811) with lean input of precursors. Systematical investigation of the microstructure evolution in the upcycling process revealed an Ostwald ripening phenomenon during particle transformation. Optimizing sintering temperature and reaction time results in single-crystal particles showing uniform Ni element distribution and valence state, clean surface, and tunable sizes. Particularly, these structure features endow upcycled NCM 811 with improved performance (198 mAh/g at C/10 and 173 mAh/g at 1 C) compared to commercial polycrystals while maintaining good cycling stability. The inventive scheme provides for affordable and efficient upcycling in today's sustainable development of NCM cells, paving the way toward next-generation LIB recycling and upcycling.

### BRIEF DESCRIPTION OF THE DRAWINGS

FIG. 1 is a schematic illustration of the direct upcycling method.

FIG. 2 is a schematic of an exemplary embodiment of the inventive process for the recovery and relithiation of spent NCM particles to produce single-crystal NCM particles.

FIGS. 3A and 3B are scanning electron microscope (SEM) images of D-NCM 111 and Ni(OH)₂, respectively. The scale bar is 4 μm. FIG. 3C is a SEM image of the homogeneous precursor following ball milling of D-NCM 111 with Ni(OH)₂. The scale bar is 1 μm.

FIG. 4 plots the results of thermogravimetric analysis (TGA) and differential scanning calorimetry (DSC) measurements during an upcycling process.

FIG. 5A is an SEM image of upcycled NCM 433 along with relative amounts of the precursors, D-NCM 111 and Ni(OH)₂, used to make the upcycled NCM 433 product. The scale bar is 2 μm. FIG. 5B illustrates X-ray diffraction (XRD) patterns of pristine polycrystalline NCM 433 (T-NCM 433), upcycled NCM 433 and their precursors with enlargement of the regions in the range of 63.0-66.0°.

FIG. 6A is an SEM image of upcycled NCM 622 along with relative amounts of the precursors, D-NCM 111 and Ni(OH)₂, used to make the upcycled NCM 622 product. The scale bar is 2 μm. FIG. 6B illustrates X-ray diffraction (XRD) patterns of pristine polycrystalline NCM 622 (T-NCM 622), upcycled NCM 622 and their precursors with enlargement of the regions in the range of 63.0-66.0°.

FIGS. 7A-7E are SEM images and size distributions of U-NCM 811 sintered at different temperatures/different times where FIG. 7A shows 850° C./10 h; FIG. 7B shows 900° C./10 h; FIG. 7C shows 900° C./12 h; FIG. 7D shows 900° C./15 h; and FIG. 7E shows 925° C./15 h.

FIG. 8 is a graph showing cycling stability at C/3 cycling of pristine polycrystalline NCM 811 (T-NCM 811) compared to upcycled, single-crystal NCM 811 sintered at 850° C. and 925° C. for 12 h.

FIGS. 9A-9G illustrate phase determination and bulk information of nickel distribution of upcycled NCM 811, where FIG. 9A provides SEM images showing size distribution of U-NCM 811 synthesized at 850° C. for 12 hours; FIG. 9B shows XRD patterns of U-NCM 811, T-NCM 811 and precursors; FIGS. 9C and 9D shows the neutron diffraction patterns of U-NCM 811 and T-NCM 811, respectively; FIG. 9E shows the SEM-EDS (energy dispersive X-ray spectroscopy) image of U-NCM 811; FIGS. 9F and 9G show the 2D XANES mapping image of Ni in U-NCM 811 and D-NCM 111, respectively.

FIG. 10 shows the SEM-EDS mapping of U-NCM 433.

FIG. 11 shows the SEM-EDS mapping of U-NCM 622.

FIGS. 12A and 12B show the 3D morphology of D-NCM 111 and U-NCM 811, respectively.

FIGS. 13A-13F illustrate microstructure and valence uniformity of upcycled NCM 811, where FIGS. 13A-13B provide the XPS spectra of D-NCM 111 and U-NCM 811, respectively, FIG. 13C is a cross-section image of U-NCM 811; FIG. 13D shows the HAADF-STEM image of upcycled NCM 811 with the inserted image of the FFT pattern; FIG. 13E shows the TEM-EDS mapping of Ni, Co and Mn; and FIG. 13F shows the EDS linear scanning with inserted elemental distribution intensity.

FIGS. 14A-14F illustrate electrochemical performance evaluation of upcycled materials, where FIG. 14A plots the voltage profile at 0.1 C of T-NCM 811 and U-NCM 811;

FIG. 14B plots the rate performance of T-NCM 811 and U-NCM 811; FIG. 14C plots the cycling performance of T-NCM 811 and U-NCM 811 at C/3 cycling; FIG. FIG. 14D shows the cycling performance of T-NCM 811 and U-NCM 811 at 1 C cycling; and FIGS. 14E-14F plot dQ/dV of U-NCM 811 and T-NCM 811, respectively, at the first two activation cycles.

FIGS. 15A-C illustrate results of electrochemical performance evaluation of upcycled materials (U-NCM 622) versus pristine (T-NCM 622), where FIG. 15A plots voltage profiles; FIG. 15B plots cycling stability at C/3 cycling; and FIG. 15C plots cycling stability at 1 C cycling.

FIGS. 16A and 16B plot dQ/dV at the first two activation cycles for U-NCM 622 and T-NCM 622, respectively.

FIG. 17 plots the cycling stability of upcycled NCM 811 particles that were pelleted at 0 MPa, 5 MPa, 10 MPa, and 15 MPa compared to loose powder.

FIG. 18 shows the voltage profiles of upcycled NCM 622 pelleted with different molar ratios of LiOH.

### DETAILED DESCRIPTION OF EMBODIMENTS

Increasing nickel content is known to directly boost the specific capacity of NCM cathodes. A similar approach should be applicable to recycling/upcycling areas. Further, recycling polycrystalline materials into single crystal cathodes has the potential for delivering superior kinetic properties and rate capabilities, along with integrity improvements. The challenge lies in controlling the uniformity of recycled particles in molten salt relithiation with mixed waste streams. The inventive approach provides methods for upcycling spent NCM cathodes while controlling the particle homogeneity and morphology that results in superior electrochemical performance.

In some aspects, methods for upcycling lithium-ion battery cathodes include providing delithiated NCM particles from spent lithium-ion battery cathodes; admixing the NCM particles with a Ni-containing precursor to produce NCM single-crystal particles; admixing the NCM single-crystal particles with a supplementary lithium source to form a mixture, wherein the supplementary lithium source comprises a single lithium salt; and treating the mixture to produce single-crystal NCM particles with increased nickel content. Use of a selected amount of a single supplementary lithium source provides control of particle uniformity with improved electrochemical performance compared to original polycrystalline NCM 811 and avoiding excess molten salt flux.

### Definitions

Unless defined otherwise, all technical and scientific terms used herein have the same meaning as is commonly understood by one of ordinary skill in the art. All patents, applications, published applications and other publications referenced herein are incorporated by reference in their entirety unless stated otherwise. To the extent publication and patents or patent applications incorporated by reference contradict the disclosure contained in the specification, the specification is intended to supersede and/or take precedence over any such contradictory material. In the event that there are a plurality of definitions for a term herein, those in this section prevail unless stated otherwise.

As used herein, the terms “NCM” or “NMC” reference to lithium nickel manganese cobalt oxides having the general formula, LiNiₓCo_{y}Mn_{1-x-y}O₂. The term “NCM” or “NMC” may be followed by three numbers indicating the relative stoichiometry of nickel, cobalt, and manganese. For instance, an NCM material consisting of 33% nickel, 33% cobalt, and 33% manganese and having a chemical formula of LiNi_{0.33}Co_{0.33}Mn_{0.33}O₂ could be represented as NCM 111 (or NCM 333 or NMC 333). Other NCM compositions may include, but are not limited to, NCM 433, NCM 532, NCM 523, NCM 622 and NCM 811.

As used herein, the term “D-NCM” refers to a delithiated NCM material having reduced lithium content compared to pristine NCM materials.

As used herein, the term “U-NCM” refers to a single-crystalline upcycled NCM material produced by treating a delithiated NCM material according to the methods described herein.

As used herein, the term “T-NCM” refers to a pristine, polycrystalline NCM material.

As used herein in the specification, “a” or “an” may mean one or more. As used herein in the claim(s), when used in conjunction with the word “comprising”, the words “a” or “an” may mean one or more than one. As used herein “another” may mean at least a second or more.

Where a range of values is provided, it is understood that the upper and lower limit, and each intervening value between the upper and lower limit of the range is encompassed within the embodiments.

The invention now being generally described, it will be more readily understood by reference to the following examples, which are included for purposes of illustration of certain aspects and embodiments of the present invention and are not intended to be limiting.

### Methods of Upcycling Spent Lithium-Ion Battery Cathodes

Embodiments of methods for upcycling of lithium-ion battery cathodes are described in Gao, et al., “Direct Upcycling of Spent LiNi_{0.33}Co_{0.33}Mn_{0.33}O₂ to Single-Crystal Nickle-Rich NCMs Using Lean Precursors”, ACS Energy Lett. 2023, 8, 10, 4136-4144 and the corresponding Supporting Information, which are incorporated by reference.

In some aspects, methods for upcycling lithium-ion battery cathodes can include providing delithiated NCM particles from spent lithium-ion battery cathodes. Once the particles are delithiated they can be mixed with a Ni-containing precursor to produce NCM single-crystal particles. In some embodiments, the delithiated NCM particles may be relithiated and purified prior to mixing with the Ni-containing precursor as described in WO 2024/123811, which is incorporated herein by reference in its entirety. The resultant NCM single-crystal particles are then mixed with a supplementary lithium source to form a mixture. The supplementary lithium source mixed with the NCM single-crystal particles can be made from a single lithium salt. The mixture is then treated to produce single-crystal NCM particles with generally increased nickel content. For example, the nickel content may be between 60% and 99%. In some embodiments, the nickel content of the single-crystal NCM particles can be 60%, 65%, 70%, 75%, 80%, 85%, 90%, 95%, 99%, or ranges including and/or spanning the aforementioned values.

In some embodiments, the source of the delithiated NCM particles can be D-NCM 111. The single crystal NCM particles with increased nickel content can be Ni-rich NCM particles, such as NCM 811, having a formula of approximately LiNi_{0.8}Co_{0.1}Mn_{0.1}O₂. In other embodiments, the single crystal NCM particles with increased nickel content can be NCM 622, having a formula of approximately LiNi_{0.6}Co_{0.2}Mn_{0.2}O₂, or NCM 433, having a formula of approximately LiNi_{0.4}Co_{0.3}Mn_{0.3}O₂.

Implementation of the inventive method may include planetary ball milling the delithiated NCM particles with the Ni-containing precursor to produce NCM single-crystal particles. The delithiated NCM particles may be ball milled with a Ni-containing precursor and a solvent, such as acetone. The nickel precursor can be Ni(OH)₂. In some embodiments, the delithiated NCM particles can be ball milled for at least about 6 h, 7 h, 8 h, 9 h, 10 h, 11 h, 12 h, 13 h, 14 h, or 15 h, or ranges including and/or spanning the aforementioned values. The ball milled mixture can then be dried for a period of several hours, for example, overnight, and may involve use of a vacuum oven.

In some aspects, the inventive method includes treating the mixture to produce single-crystal NCM particles by pelletizing the mixture to produce a pellet; and sintering the pellet to produce single-crystal Ni-rich NCM particles. The single-crystal NCM particles with increased nickel content can include Ni-rich NCM particles, wherein at least 50% of the transition metal content can comprise nickel. In some embodiments, the reaction mixture can be pelletized at a pressure of above 0 MPa. The reaction mixture can be pelletized at a pressure of at least about 1 MPa, 2 MPa, 3 MPa, 4 MPa, 5 MPa, 6 MPa, 7 MPa, 8 MPa, 9 MPa, 10 MPa, 11 MPa, 12 MPa, 13 MPa, 14 MPa, 15 MPa, 16 MPa, 17 MPa, 18 MPa, 19 MPa, 20 MPa, or ranges including and/or spanning the aforementioned values. In some embodiments, the reaction mixture can be pelletized at a pressure of at least about 5 MPa, at least about 10 MPa, or at least about 15 MPa.

In some implementations of the inventive method, the ball milled mixture can be pelleted with a molar excess of the lithium salt. The mixture can comprise at least about a 5% molar excess (1.05× molar ratio—based on the stoichiometry in the final product, Li_{1.05}NiₓCo_{y}Mn_{z}O₂). In other embodiments, the mixture can comprise at least about a 10% molar excess (1.1× molar ratio—based on the stoichiometry in the final product, Li_{1.1}NiₓCo_{y}Mn_{z}O₂). The mixture may comprise about a 5% molar excess of the lithium salt or about a 10% molar excess of the lithium salt. In some embodiments, the lithium salt can be LiOH.

In some embodiments of the methods disclosed herein, the pellet can be sintered at a temperature within range of about 850° C. to about 950° C. The pellet can be sintered at about 850° C., 860° C., 870° C., 880° C., 890° C., 900° C., 910° C., 920° C., 930° C., 940° C., or 950° C., or ranges including and/or spanning the aforementioned values. The ramping rate may be about 10° C./min. The pellet may be sintered under pure oxygen. As part of the sintering step, the pellet can be held at 480° C. for about 3 h with a ramping rate of about 5° C./min. Following the hold period at 480° C., the pellet may be increased to and held at a higher temperature for at least 10 h, 12 h, or 15 h with a ramping rate of 10° C./min.

In some implementations of the inventive method, the pellet can be sintered for at least about 1 h, 2 h, 3 h, 4 h, 5 h, 6 h, 7 h, 8 h, 9 h, 10 h, 11 h, 12 h, 13 h, 14 h, or 15 h, or ranges including and/or spanning the aforementioned values. The pellet may be sintered for at least about 10 h, between about 10 h and about 15 h, or for about 12 h.

In some embodiments, the single-crystal, Ni-rich NCM particles can be NCM 811 and may have a surface area of approximately 1.74 m²/g. The single-crystal NCM particles can have an average particle size (D₅₀) of about 1.6 μm to about 4.9 μm, an average particle size (D₅₀) of about 1.7 μm to about 2.5 μm, or an average particle size (D₅₀) of about 1.8 μm.

In some embodiments, the XPS I(003)/I(104) peak intensity ratio of the single-crystal NCM particles can be greater than 1.6, or greater than about 1.85.

### EXAMPLES

Aspects of the inventive approaches are further described in the following examples, which are illustrative and not intended to be limiting. Those in the art will appreciate that additional implementations and embodiments also fall within the scope of inventive methods as it is described herein above and in the claims.

### Example 1: Synthesis of NCM 811

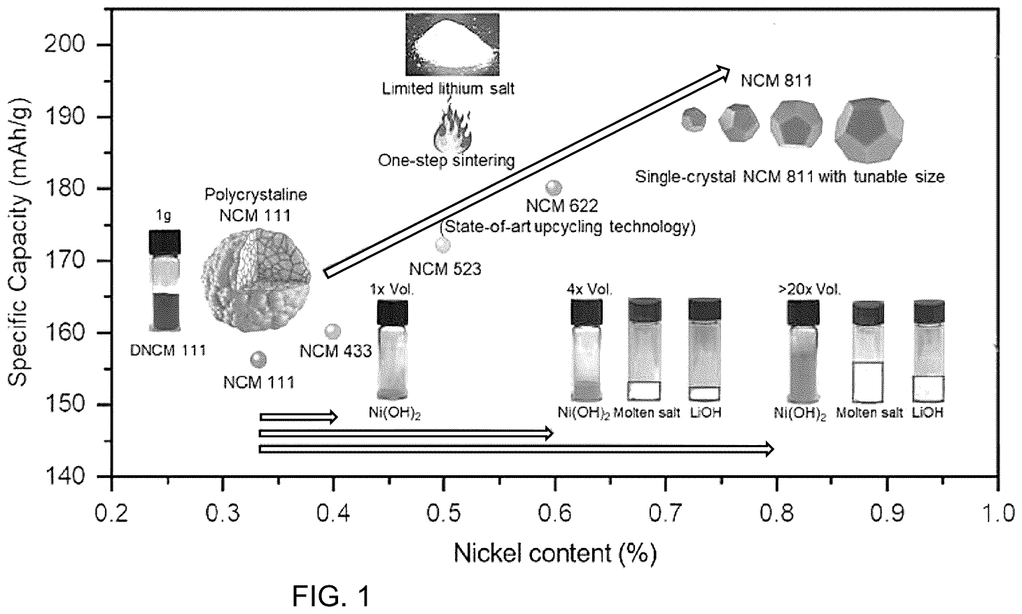

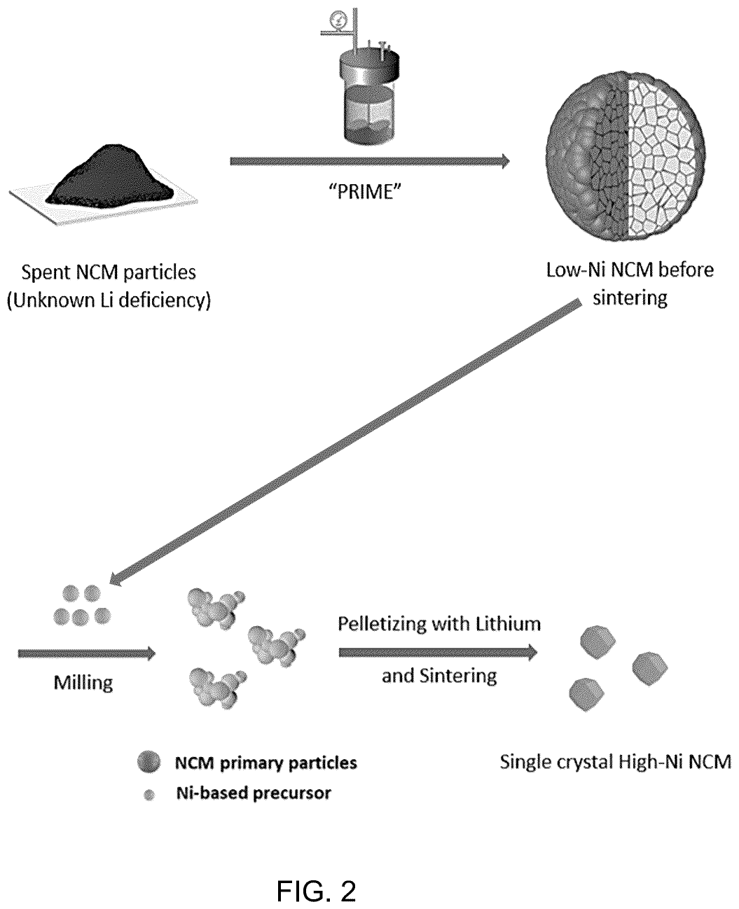

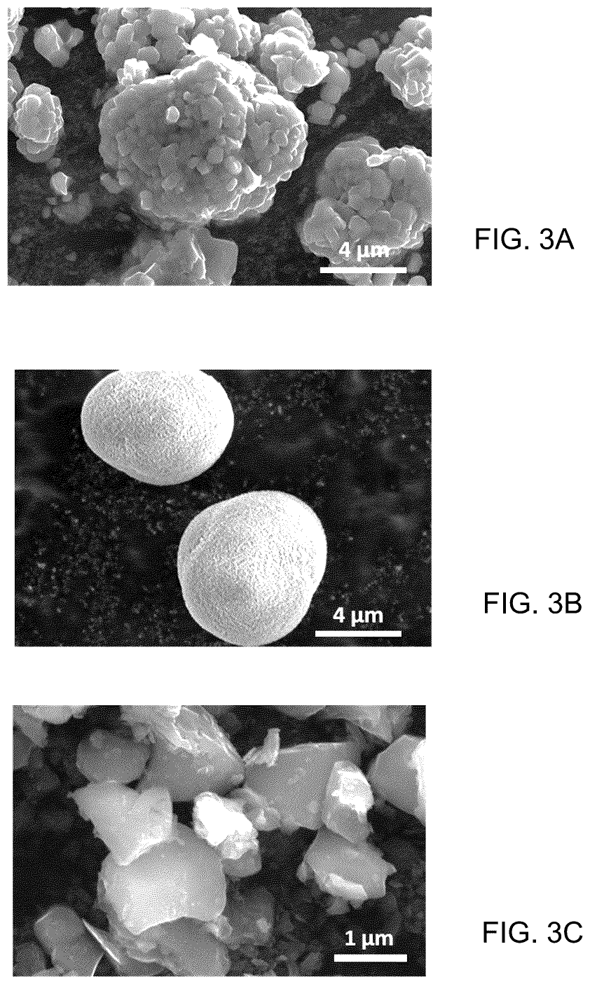

FIGS. 1 and 2 diagrammatically illustrate features of an embodiment of the inventive method to upgrade the polycrystalline D-NCM 111 to higher nickel NCM with single-crystal morphology control using a limited Li supplementary source. The spent (delithiated) polycrystalline NCM particles (e.g., D-NCM 111) are mixed with Ni-containing precursors (e.g., Ni(OH)₂) by ball milling to form a homogenous mixture, which is subject to relithiation with a limited amount of LiOH (by the sintering process) to obtain single-crystal NCM particles with a clean surface (no lithium salt residuals), well-defined structure and enhanced rate performance. The amount of molten salt is based on the state-of-the art method by Ma et al.'s work. Chemically delithiated NCM 111 with approximately 10% of Li loss, denoted as “D-NCM 111” was produced. Pristine NCM 111 was reacted with an aqueous solution of potassium persulfate to leach out remaining lithium. Afterwards, the leached material was washed with water, followed by treatment with acetonitrile, and finally the solution was dried under vacuum at ambient conditions. The D-NCM111 was manufactured at 1 kg per batch size and utilized as the starting material in the process studies. Ni(OH)₂ with a spherical particle morphology was also provided. SEM images of D-NCM 111 and the Ni(OH)₂ precursor are provided as FIGS. 3A-3B. The scale bar is 4 μm.

The morphology evolution reveals the transformation of polycrystalline particles to single-crystal particles. To achieve such a transformation, 10 g of the D-NCM 111 was first pulverized into primary grains via planetary ball milling (PQ-N04 series from Across International) with the Ni(OH)₂ precursor in 15 mL of acetone at 600 rpm for 12 h, facilitating the diffusion of extra Ni into the NCM bulk phase. The homogeneous precursor mixture was collected after drying overnight in a vacuum oven.

The homogenous precursor (FIG. 3C (scale bar 1 μm)) was then subjected to a relithiation sintering step with 10% molar excess LiOH (to compensate for Li loss during sintering step). The ball milled mixture (1 g) was pelleted with a 1.1× molar ratio (based on the stoichiometry in the final product, Li_{1.1}NiₓCo_{y}Mn_{z}O₂) of LiOH.

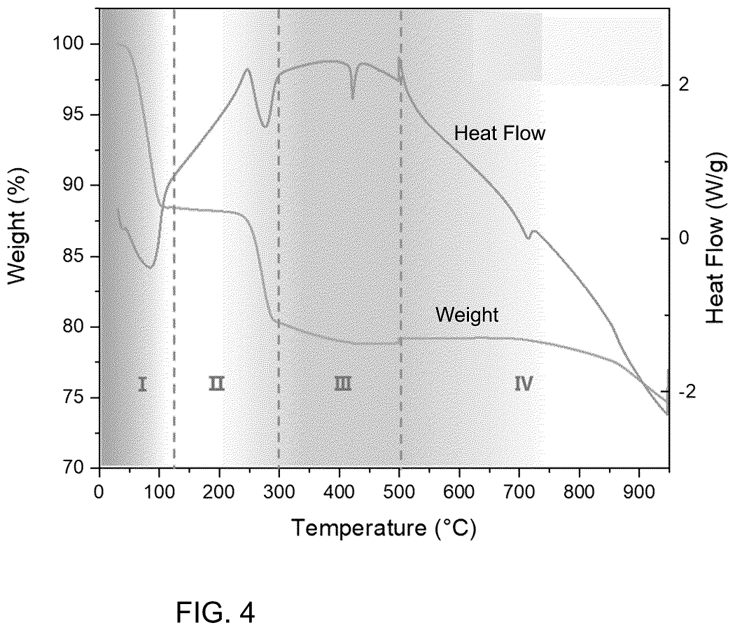

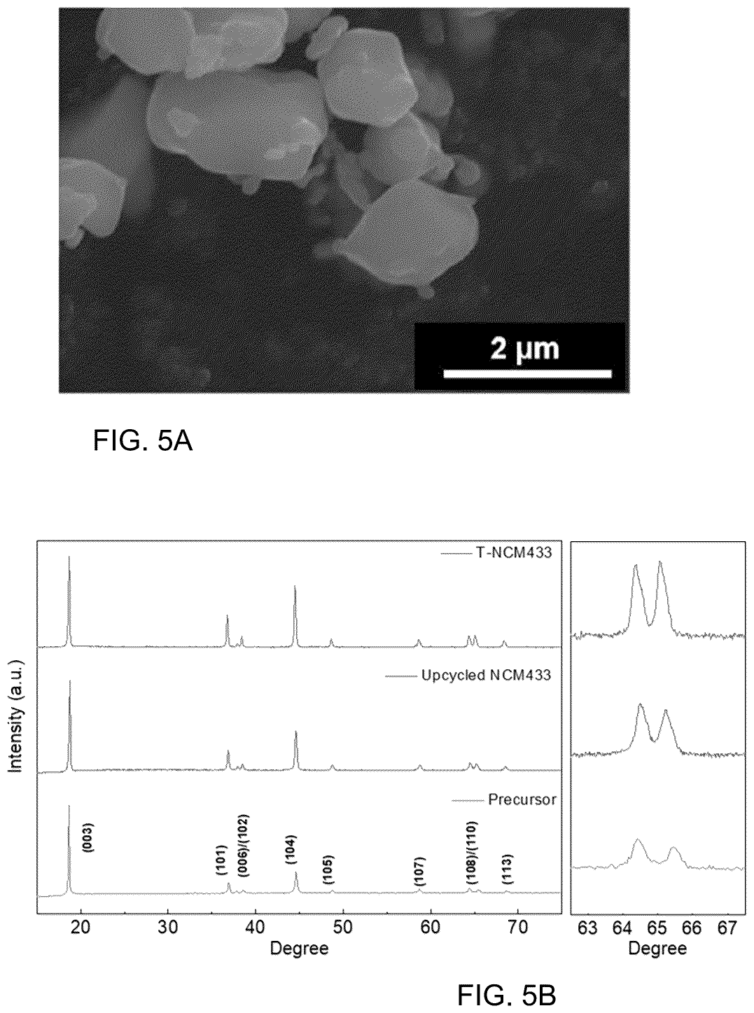

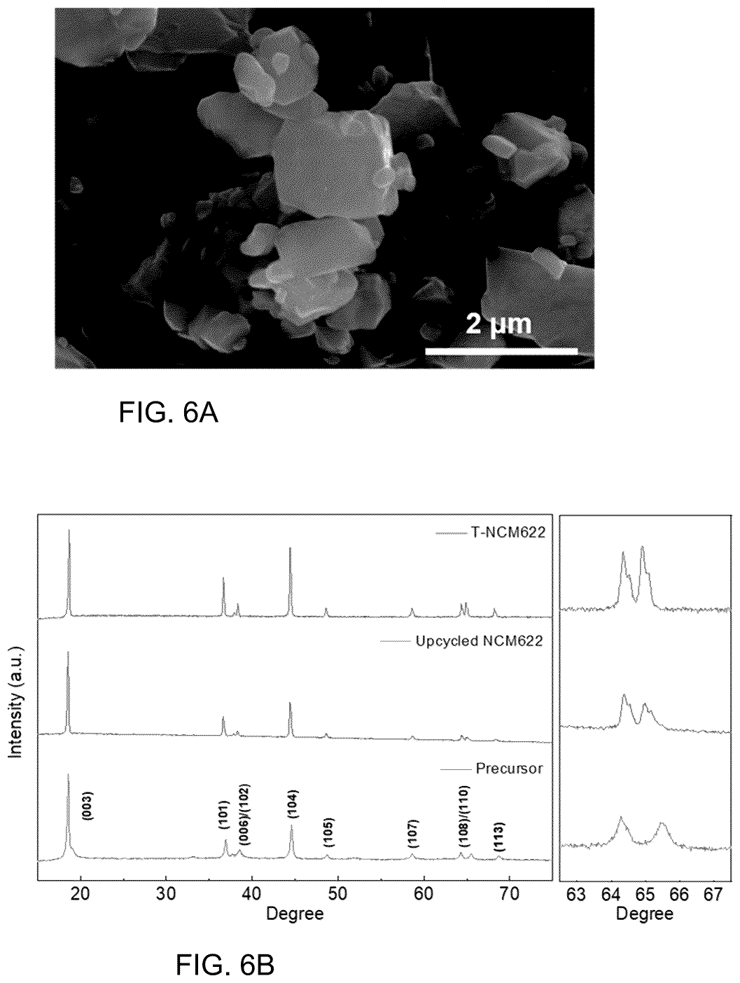

The thermogravimetric analysis (TGA) and differential scanning calorimetry (DSC) curve of the upcycling process were determined in alumina pans by an Instruments™ Discovery SDT 650™ simultaneous DSC/TGA. The TGA-DSC analysis in FIG. 4 illustrates the compositional evolution during the sintering process. In Zone I, LiOH·H₂O loses H₂O to form LiOH. In Zone II, Ni(OH)₂ melts and decomposes into NiOₓ. In Zone III, LiOH starts to melt. NiOₓ and D-NCM merge into LiOH solution. In Zone IV, D-NCM starts to decompose and reacts with NiOₓ. For the sintering step, the temperature was held at 480° C. for 3 h with a ramping rate of 5° C./min to form a uniform LiOH solution with D-NCM and a decomposed Ni(OH)₂ precursor. After the hold period, the temperature was ramped up to the specified high temperature. Following an extended high temperature sintering period of about 10 h to 15 h, i.e., between 850° C. and 950° C., a fully-lithiated single-crystal NCM 811 was obtained with no significant lithium salt residual on the surface. Similar methods were applied to synthesize NCM 433 and NCM 622 with good control of composition (Table 1) and phase purity (FIGS. 5A-6B). The corresponding samples under the optimal conditions are denoted as “U-NCM 433”, “U-NCM 622”, and “U-NCM 811”, respectively.

The chemical composition of NCM powders was evaluated by inductively coupled plasma mass spectrometry (ICP-MS, Thermo Scientific, iCAP RQ model). The crystal structures of the NCM powders were examined by X-ray powder diffraction (XRD) employing a Bruker D2 Phaser (Cu Kα radiation, λ=1.5406 Å). The morphology of the NCM powders was observed by an FEI Apreo LoVac scanning electron microscope (SEM) with an X-Max 80 EDS detector. The particle size distribution was analyzed with Nano Measurer software. Due to the irregular shape of the single crystals, the greatest dimension was considered to be the diameter of the particles.

TABLE 1
ICP result of pristine NCM particles, precursor
mixtures and upcycled NCM particles.

| Sample | Li | Ni | Co | Mn |
|---|---|---|---|---|
| D-NCM 111 | 0.901 | 0.334 | 0.335 | 0.332 |
| T-NCM 433 | 1.006 | 0.401 | 0.294 | 0.305 |
| U-NCM 433 | 1.025 | 0.377 | 0.309 | 0.314 |
| D-NCM 111 + Ni(OH)₂ (622) | 0.597 | 0.594 | 0.200 | 0.206 |
| T-NCM 622 | 1.04 | 0.612 | 0.189 | 0.200 |
| U-NCM 622 | 1.061 | 0.599 | 0.202 | 0.207 |
| D-NCM 111 + Ni(OH)₂ (811) | 0.284 | 0.802 | 0.096 | 0.102 |
| T-NCM 811 | 1.022 | 0.801 | 0.096 | 0.103 |
| U-NCM 811 | 1.064 | 0.801 | 0.097 | 0.102 |

Compared with single-crystal NCM 622 obtained using excess amounts of molten salt flux of Li mixtures reported in recent works^{23, 24, 26}, embodiments of this “lean” LiOH approach enabled a better control of homogeneity as it is challenging to upgrade into single-crystal NCM 811 from the same starting material, D-NCM 111, with a large excess of Li salt, which also involves a large amount of transition metal diffusion between metal precursors and the existing NCM host. As shown in FIG. 1, more than 20× or 4× of the volume of Ni(OH)₂ is required to reach the compositional formula for the final NCM 811 product compared with NCM 433 or NCM 622 upcycling. More importantly, instead of using a large amount of mixed lithium salts to form the molten salt system, this direct upgrading process utilized a minimum amount of a single lithium salt (e.g., LiOH) to compensate for the lithium loss in spent NCM and to react with the newly added Ni precursor to form the desired Ni-rich NCM single-crystals with high uniformity and tunable particle sizes. This demonstrated a simple yet efficient method to upgrade NCM 111 into single-crystal NCM 811 with high elemental integrity and good electrochemical performance without any excess molten salt flux. This can be critical for low-cost and scalable upcycling. Particularly, in large scale operations this lean salt upcycling process may significantly reduce the water and energy usage for washing and reclaiming the extra lithium.

### Example 2: Temperature-Dependent Size and Morphology Control

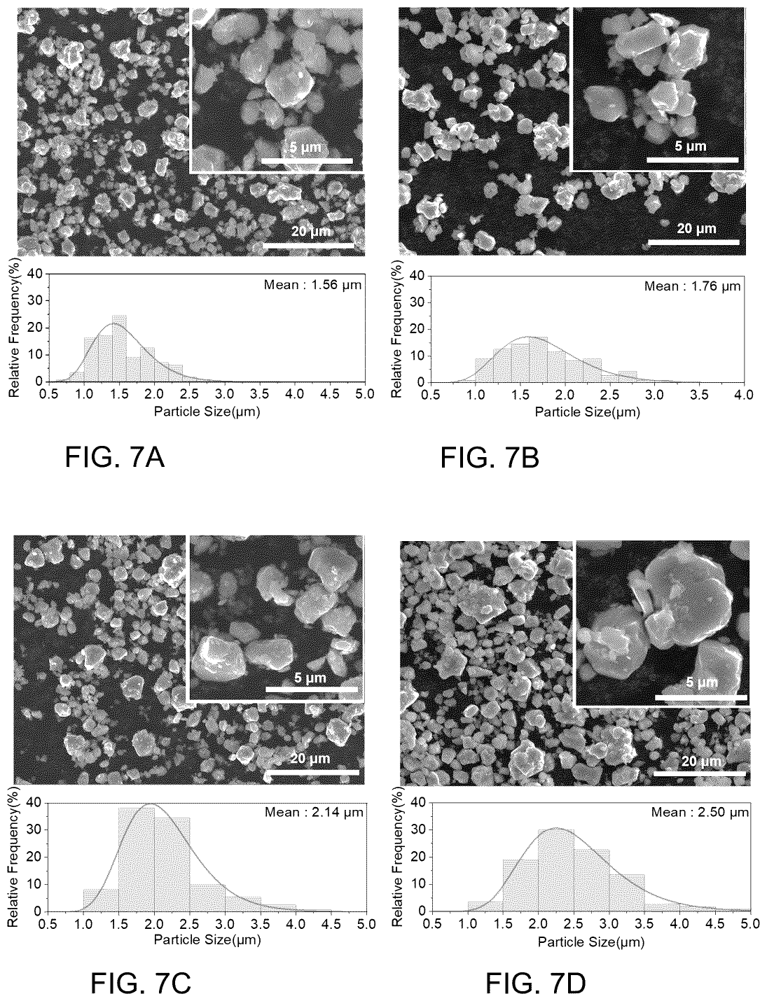

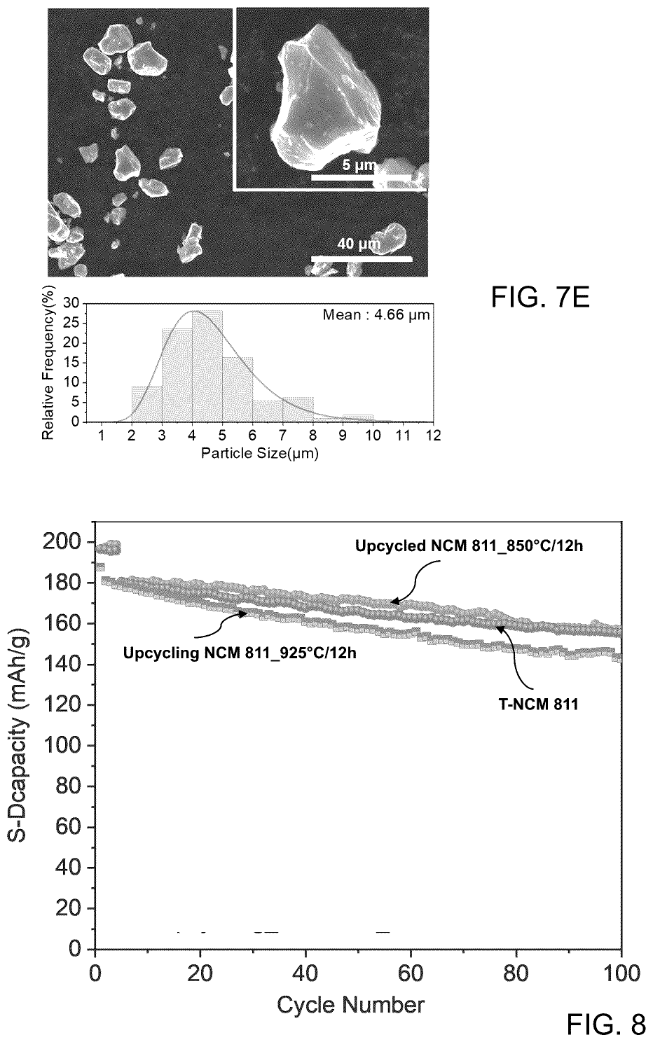

The ability to control the size of the upcycled particles was evaluated by modifying the sintering conditions. This process has revealed the occurrence of the Ostwald ripening phenomenon, which is caused by variations in the solubility of smaller and larger particles in the surrounding medium. This can affect the diffusion of Ni into D-NCM 111, merging in the mixture of Ni(OH)₂ and LiOH. By extending the sintering time from 10 h to 15 h at 900° C., an obvious growth trend of primary particle sizes was observed in “U-NCM 811-900-10 h”, “U-NCM 811-900-12 h” and “U-NCM 811-900-15 h” with the D₅₀ size of approximately 1.8, 2.1, and 2.5 m, respectively (FIGS. 7B-D). Additionally, the smallest (1.6 μm) and largest (4.9 μm) D₅₀ sizes are obtained for U-NCM 811-850-10 h (FIG. 7A) and U-NCM 811-925-15 h (FIG. 7E).

The morphology based on temperature dependence can be ascribed to the higher solubility and mobility of the reactive components, allowing Ni diffusion and lithiation at higher temperature. These manners of crystal growth have been observed in the flux growth of oxides, suggesting that the crystal size increases with the reaction time and holding temperature. Thus, by selection of sintering duration and temperature, the morphology of the upcycled NCM 811 material can be controlled. The conversion of particles and their morphology change was thus featured as the Ostwald ripening phenomenon, which occurs during the flux growth of oxides when D-NCM particles merge and grow at the expense of the Ni precursor via dissolution and precipitation.

As shown in FIG. 8, single-crystal U-NCM 811-850-12 h had a greater initial specific-discharge capacity and a greater sustained capacity compared to U-NCM 811-925-12 h, which had a larger mean particle size. U-NCM 811-950-12 h also demonstrated improved electrochemical performance compared to polycrystalline pristine NCM 811 (T-NCM 811).

### Example 3: Characterization of Upcycled NCM Crystals

With the aforementioned direct upcycling method, the Ni-rich NCM single-crystals were obtained with desired compositions, confirmed by inductively coupled plasma mass spectrometry (ICP-MS) (Table 1). Note that the 10% Li-deficient D-NCM 111 (Li_{0.901}Ni_{0.334}Co_{0.335}Mn_{0.331}O₂) was converted into fully-lithiated NCM single-crystal particles (Li_{1.025}Ni_{0.377}Co_{0.309}Mn_{0.314}O₂, Li_{1.061}Ni_{0.599}Co_{0.202}Mn_{0.207}O₂, and Li_{1.064}Ni_{0.801}Co_{0.097}Mn_{0.102}O₂) in the form of single-crystal particles.

TABLE 2
Brunquer-Emmett-Teller (BET) surface area analysis of pristine
polycrystal NCM 811 and upcycled single-crystal NCM 8111

| Sample | Surface Area (m²/g) |
|---|---|
| T-NCM 811 (poly) | 1.20 |
| U-NCM 811 | 1.74 |

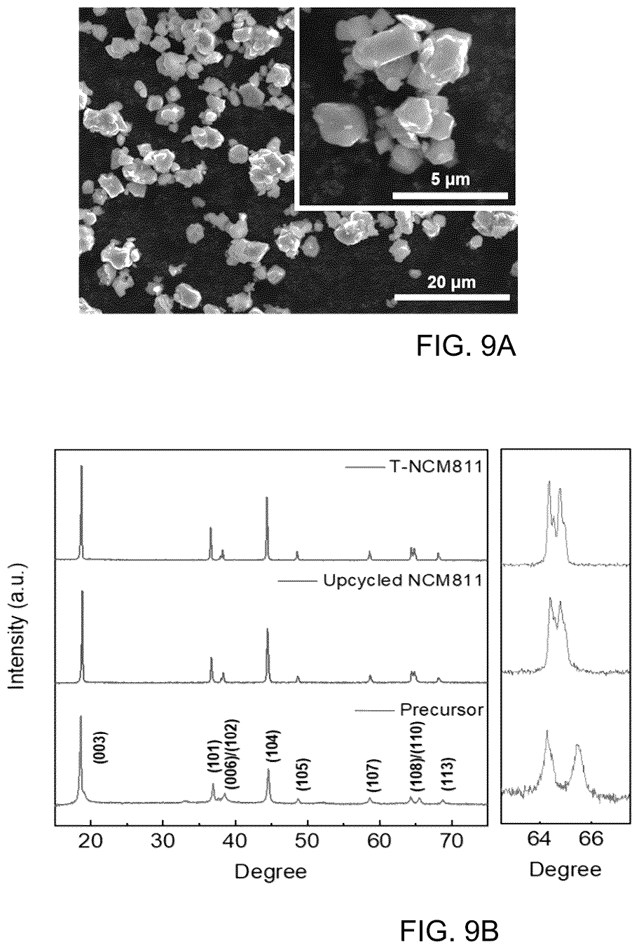

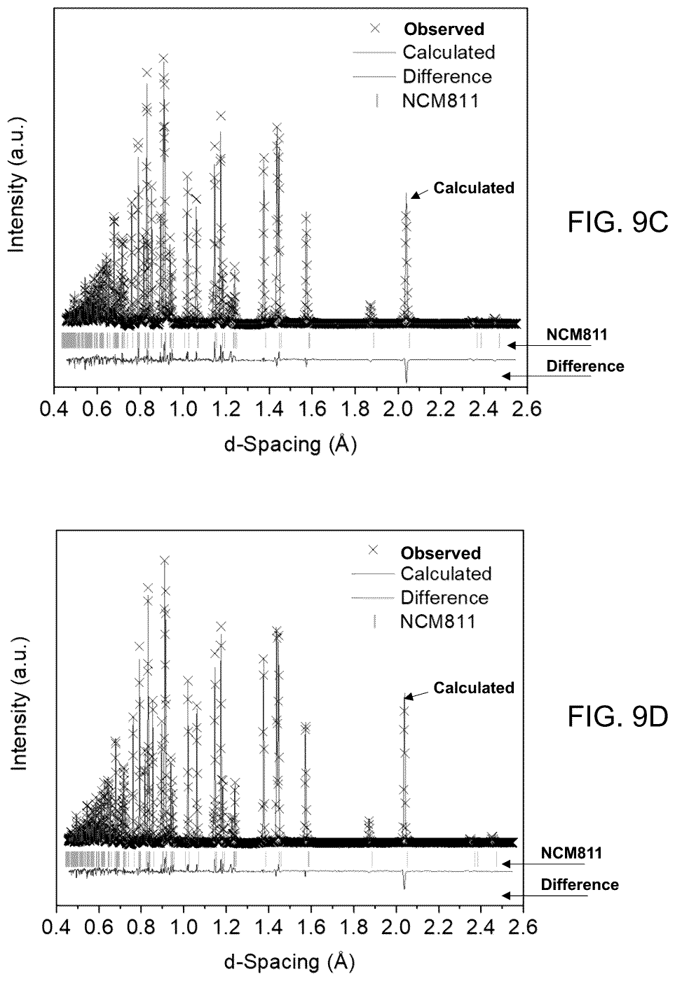

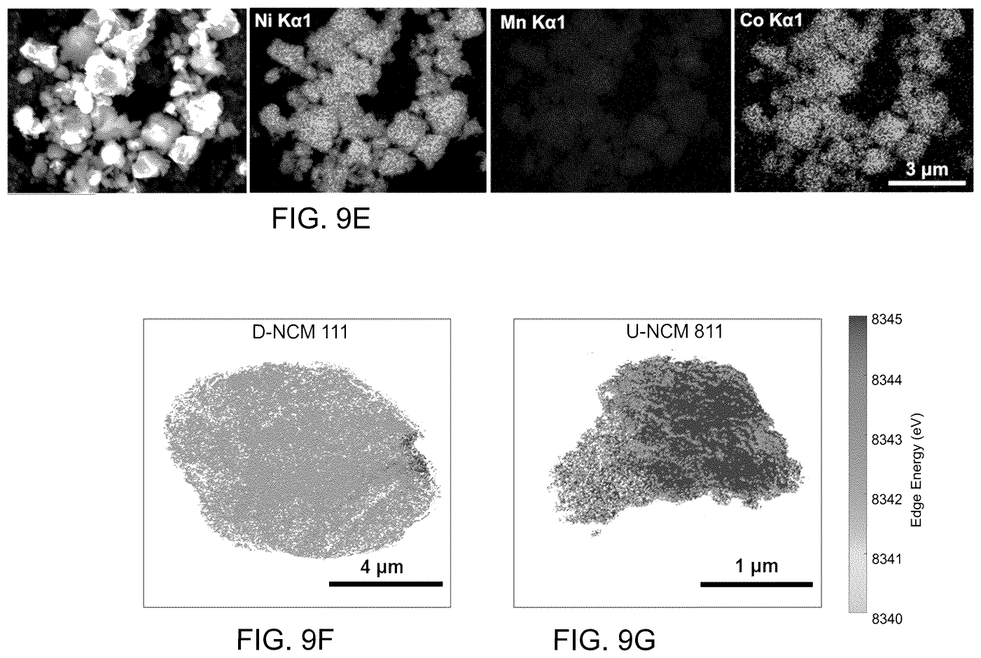

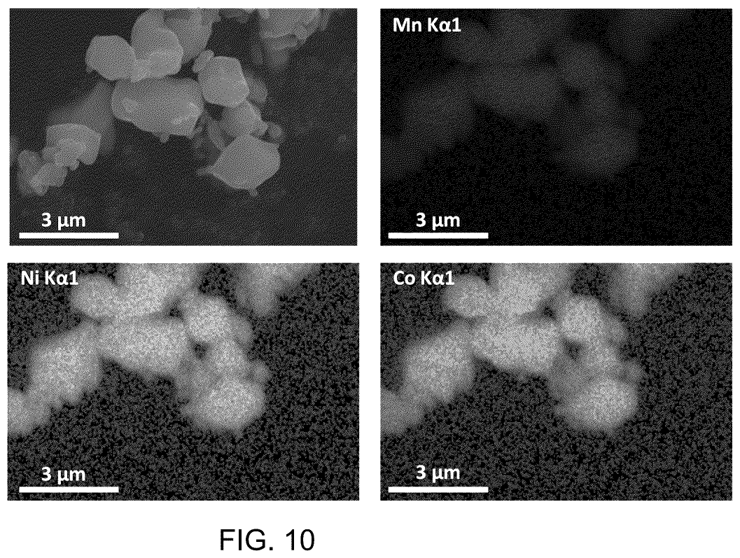

Brunauer-Emmett-Teller (BET) surface area analysis was conducted using an Autosorb IQ gas adsorption analyzer (Anton Parr) following the multiple points BET method, with the adsorption-desorption isotherms of nitrogen. Samples were degassed at 300° C. for 6 hours to remove the residual molecules before characterization. According to the BET analysis (Table 2), U-NCM 811 showed a relatively higher surface area (1.74 m²/g) than that of polycrystalline T-NCM 811 (1.20 m²/g), which was expected from its smaller particle size. To illustrate the effectiveness of our developed synthesis method, SEM images and XRD patterns of U-NCM 811 with optimized synthesis conditions are shown in FIGS. 9A-9B. Meanwhile, FIGS. 5A-6B illustrate the XRD patterns of other upcycled cathode samples, including both NCM 433 and NCM 622. Rietveld refinement was performed on all the XRD patterns using the GSAS software with EXPGUI as the graphic user interface (Table 3).

TABLE 3
XRD refinement results of upcycled NCM particles

| Sample | a/Å | c/Å | (003)/(104) | R_{wp}/% | R/% |
|---|---|---|---|---|---|
| T-NCM 111 | 2.859 | 14.257 | 1.443 | 3.93 | 2.05 |
| T-NCM 433 | 2.867 | 14.248 | 1.456 | 4.37 | 3.02 |
| U-NCM 433 | 2.867 | 14.244 | 1.861 | 3.39 | 2.63 |
| T-NCM 622 | 2.8712 | 14.225 | 1.427 | 3.44 | 3.12 |
| U-NCM 622 | 2.8710 | 14.198 | 1.770 | 5.45 | 3.15 |
| T-NCM 811 | 2.8760 | 14.218 | 1.485 | 3.45 | 3.09 |
| U-NCM 811 | 2.8735 | 14.179 | 1.657 | 4.45 | 3.58 |

The standard pattern of a hexagonal α-NaFeO₂ type structure with the R-3m space group was validated in all samples without detectable phase impurities. The peak positions were well matched in all regenerated samples and the virgin polycrystalline NCM sample (T-NCM 433, T-NCM 622, and T-NCM 811), indicating that the pure high Ni phase was successfully constructed. Moreover, the separation of (108)/(110) peaks became narrower when the Ni content increased in NCM, indicating the smaller c/a ratio in a hexagonal lattice³¹. The regenerated samples maintained the same peak separation with T-NCM 433, T-NCM 622 and T-NCM 811 while the precursor samples had larger distances. The refinement results show that the c-axis lattice parameter (14.257 Å in T-NCM 111, 14.248 Å in U-NCM 433, 14.198 Å in U-NCM 622, 14.179 Å in U-NCM 811) of the NCM cathodes decreased, while the a-axis parameter and lattice volume increased with the increase in the Ni content in the structure of the cathodes (2.859 Å in T-NCM 111, 2.867 Å in U-NCM 433, 2.871 Å in U-NCM 622, 2.874 Å in U-NCM 811) (Table 3). This can be attributed to the increased proportion of Ni³⁺ ions and the simultaneous decrease in the concentration of Mn⁴⁺ ions. Furthermore, the peak intensity ratio of I(003)/I(104) was above 1.85 in single-crystal samples compared to 1.44 in the pristine polycrystalline particles, which indicated the highly ordered lattice structure and lower Li/Ni mixing in single-crystal particles. The integrated intensity ratio of the (003) and (104) peaks I(003)/I(104) has been considered as one of the indicators of the degree of cation mixing due to the fact that migration of Ni ions from the octahedral (3a) site to the Li (3b) site (and vice versa) is reported to weaken the intensity of the (003) line, whereas such migrations do not alter the (104) peak intensity and, as a result, the ratio typically decreases with increased cation mixing.

### Example 4: Neutron Diffraction Studies

To further quantify the occupancy of Li sites and the percentage of Li/Ni anti-site defects in the lattice, neutron diffraction was conducted on the T-NCM 811 and U-NCM 811 (FIGS. 9C and 9D). Time-of-flight (TOF) powder neutron diffraction was measured by a VULCAN instrument. The diffraction pattern was measured at the detector banks at 20=±90°, equipped with 5 mm receiving collimators. Neutron powder diffraction patterns were collected in the high-intensity mode (Δd/d˜0.45%) for a duration of 2 h under the nominal 1.4 MW SNS operation and then processed using VDRIVE software. Rietveld refinement against the neutron diffraction was performed using General Structure Analysis System (GSAS) software with the EXPGUI interface.

Both samples demonstrated the 03 type layered α-NaFeO₂ structure, which consists of a closely packed oxygen array occupying the 6c sites. Li and transition metals (Ni, Co and Mn) occupy the octahedral sites along the (111) plane, named as 3a and 3b sites³⁵. Typically, the Li/Ni anti-sites defects are composed of Li⁺ and Ni²⁺ due to their closer radius (0.76 Å for Li⁺, 0.69 Å for Ni²⁺)³⁶. According to the Rietveld refinement results listed in Table 3, the upcycled NCM 811 contained less oxygen loss and less Ni²⁺ compared with pristine NCM 811 due to the highly ordered structure inhibiting oxygen release. Hence, lower Li/Ni mixing (3.54%) was observed in U-NCM 811 compared with 3.97% in T-NCM 811.

### Example 5: Transition Metal Distribution Studies

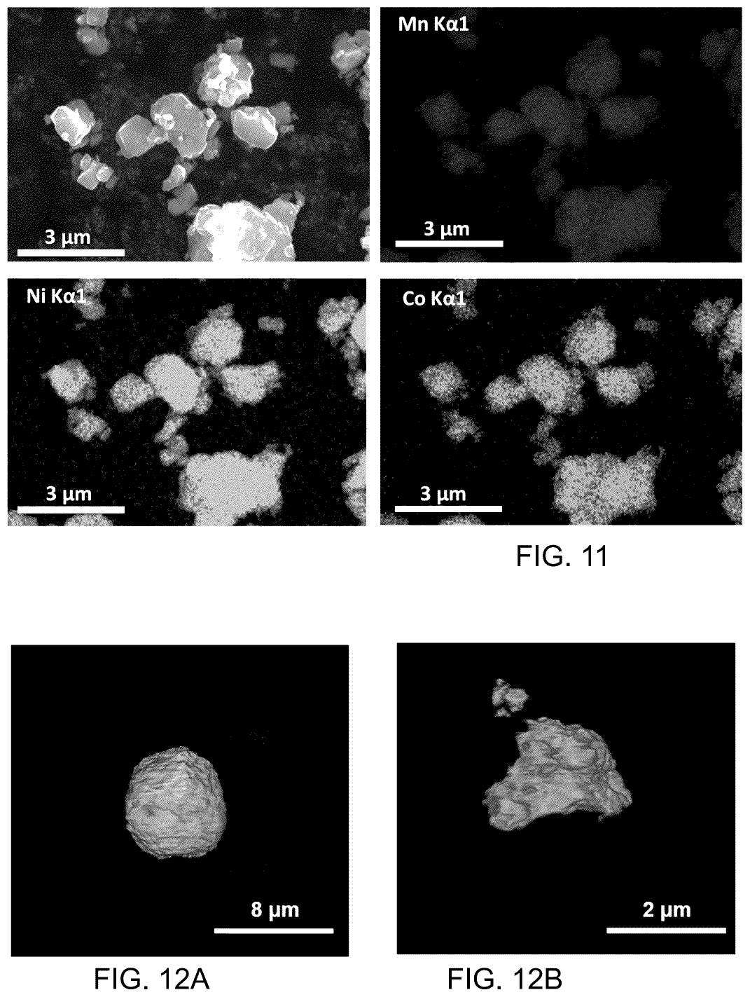

To confirm the uniformity of the transition metal distribution in the U-NCM 811 sample, SEM-EDS was performed, and the related mappings are shown in FIG. 9E (scale bar 3 μm). It is apparent that Ni, Co, and Mn were uniformly distributed along with the whole single-crystal particles. Similarly, the elemental distribution in upcycled NCM 433 and NCM 622 was also confirmed by SEM-EDS in FIGS. 10 and 11 (scale bar 3 μm), respectively, showing uniform composition. Moreover, a 3D tomography by transmission X-ray microscopy (TXM) and 2D X-ray Absorption Near-Edge Structure (XANES) mapping with the resolution of 28.7 nm per pixel were performed for a detailed investigation on Ni valence distribution to reveal the element uniformity with good resolution.

Spectroscopic transmission X-ray microscopy (TXM) was performed by a 6-2c beamline. 8.95 keV X-rays were utilized to characterize the particle morphology. The NCM particles were placed in a quartz tube and sealed with epoxy in an Ar-filled glovebox. The tomography data were taken over an angular range of 180°. The field of view of each tile was 16 m, consisting of 1024×1024 pixels, with a pixel size of 28.7 nm. The images were then processed in the TXM-Wizard software suite, with reference correction, energy average, image alignment, and 2D X-ray Absorption Near-Edge Structure (2D XANES) analysis. The edge energy maps saved by TXM-Wizard were exported into 64-bit .raw files using MATLAB® for visualization.

FIGS. 12A-12B provide volume renderings of a primary particle from U-NCM 811 and D-NCM 111, respectively. The spherical D-NCM 111 particle with secondary structure was >5 m in diameter, while the single-crystal U-NCM 811 was approximately 1.8 m with an anomalous shape. The 2D XANES mapping illustrates that the near-edge energy of Ni shifted to higher energy with good uniformity after the upcycling process (FIGS. 9F-9G). Therefore, a well-defined bulk structure characterized by a highly uniform Ni distribution was achieved through this simple sintering method with a limited lithium source, resulting in upcycled single-crystal NCM 811 products.

To investigate the valence distribution of transition metals from the upcycled cathode material, XPS was performed on the upcycled NCM 811 and D-NCM 111. X-ray photoelectron spectroscopic (XPS) measurement was conducted with an AXIS Supra by Kratos Analytical with an Al Ka anode source working at 15 kV and 108 Torr chamber pressure. The spectra data were processed by CasaXPS software. All spectra were calibrated with the hydrocarbon C is peak at 284.6 eV. The cross-section images of upcycled NCM experiments were performed using a FEI Scios dual beam focused ion beam (FIB). Aberration corrected scanning transmission electron microscopy (AC-STEM) and energy-dispersive X-ray spectroscopy (EDS) were conducted using a JEOL JEM-ARM 300F at 300 kV.

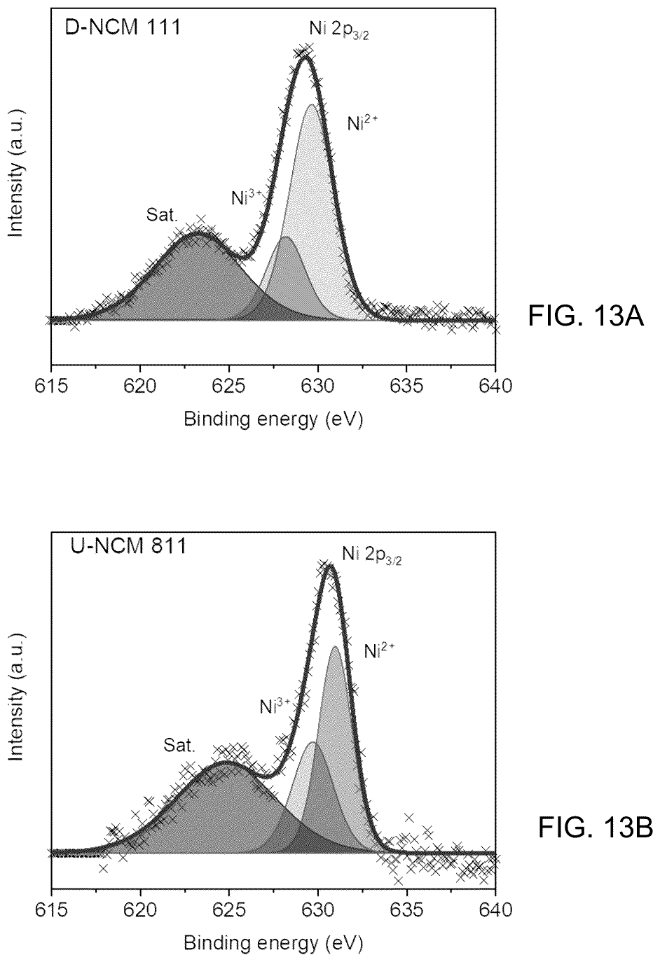

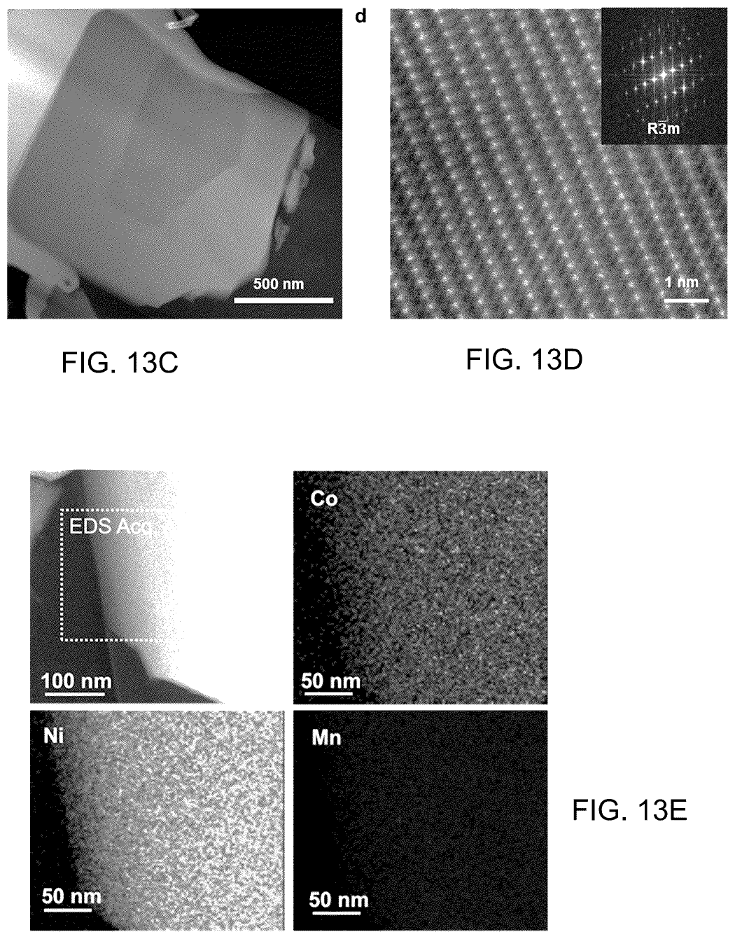

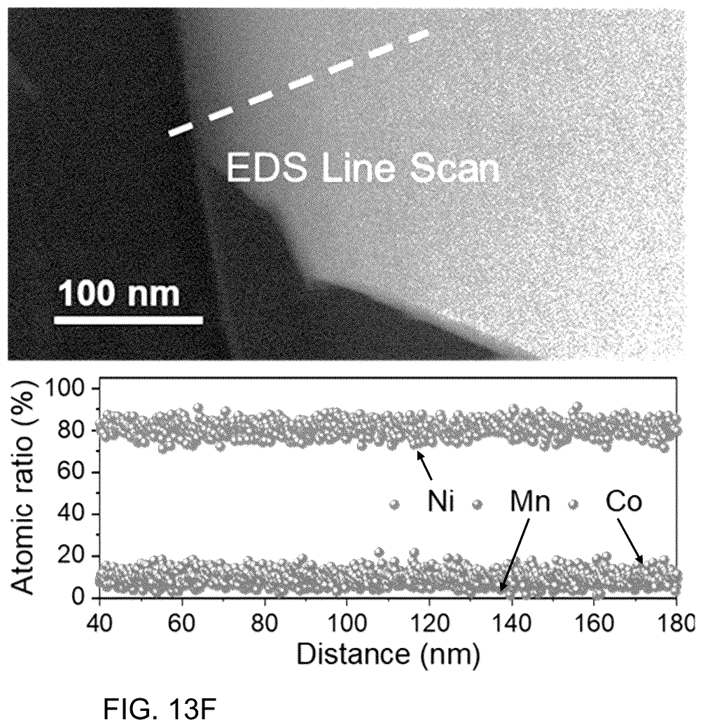

The fitted Ni²⁺/Ni²⁺ spectra in FIG. 13A illustrates an unneglectable amount of Ni³⁺ observed in D-NCM 111 due to a significant lithium deficiency in D-NCM 111. FIG. 13B reveals a higher Ni³⁺/Ni²⁺ ratio in upcycled NCM 811 in a fully-lithiated status, suggesting that the average valence of Ni increased when its content increased from 33% in D-NCM 111 to 80% in U-NCM 811. The XPS results are consistent with the observation from 2D XANES mapping.

To further understand the microstructure of upcycled materials, the FIB lamella of the U-NCM 811 was prepared and examined by scanning transmission electron microscopy (STEM). FIG. 13C shows the cross-sectional view of U-NCM 811 without any cavities, cracks, and clear grain boundaries. The high-resolution high-angle annular dark-field (HAADF)-STEM images with fast Fourier transform (FFT) pattern again confirmed the pure phase of α-NaFeO₂-type layered structures (FIG. 13D). EDS mapping illustrated the uniform local distribution of Ni, Mn and Co at tens of nanometer scale (FIG. 13E). The linear scanning validated the distribution of Ni, Mn and Co with exact 8:1:1 ratio with high uniformity in the grain of interest (FIG. 13F).

### Example 6: Electrochemical Performance of Upcycled NCM Cells

The electrochemical performance of the pristine and upcycled NCM 811 cells was evaluated by half cells at the potential between 2.8 and 4.3 V (versus Li/Li⁺). Pristine polycrystalline NCM 111, NCM 433, NCM 622, and NCM 811 (noted as T-NCM 111, T-NCM 433, T-NCM 622 and T-NCM 811) were obtained. The active materials were mixed with polyvinylidene difluoride (PVDF) and Super P65 in NMP at a mass ratio of 8:1:1 to make electrode slurries. Then the formed slurries were cast on an aluminum foil using a doctor blade and dried in a vacuum at 120° C. for 6 h. The electrodes were cut and compressed by rolling. The areal mass loading of electrodes was around 6 mg/cm². Coin cells were assembled with a Li metal disc (thickness 1.1 mm) as the counter electrode, 1.2 M LiPF₆ in EC/EMC=3:7 as the electrolyte, and a tri-layer membrane (Celgard 2325) as the separator. Galvanostatic charge-discharge was carried out using a Neware battery testing system in the potential range of 2.8-4.3 V at different rates for 100 cycles after C/10 in the first 3 activation cycles.

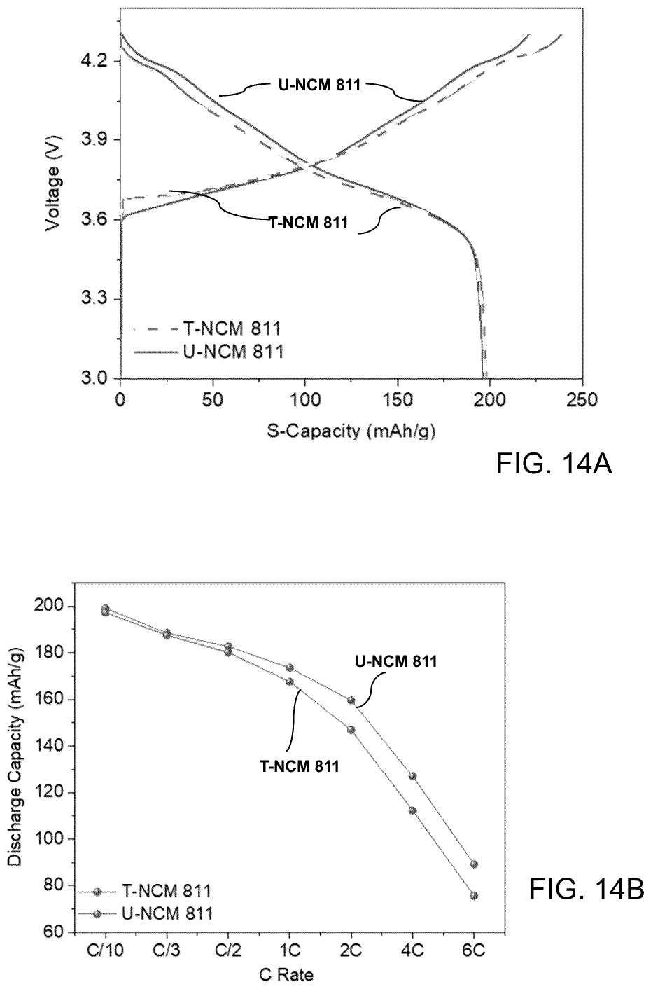

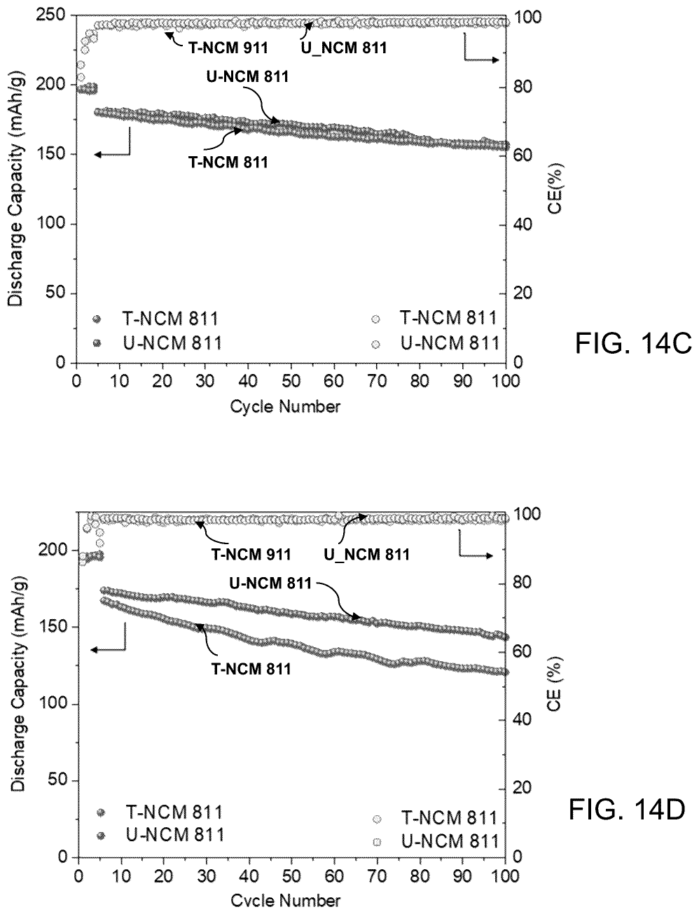

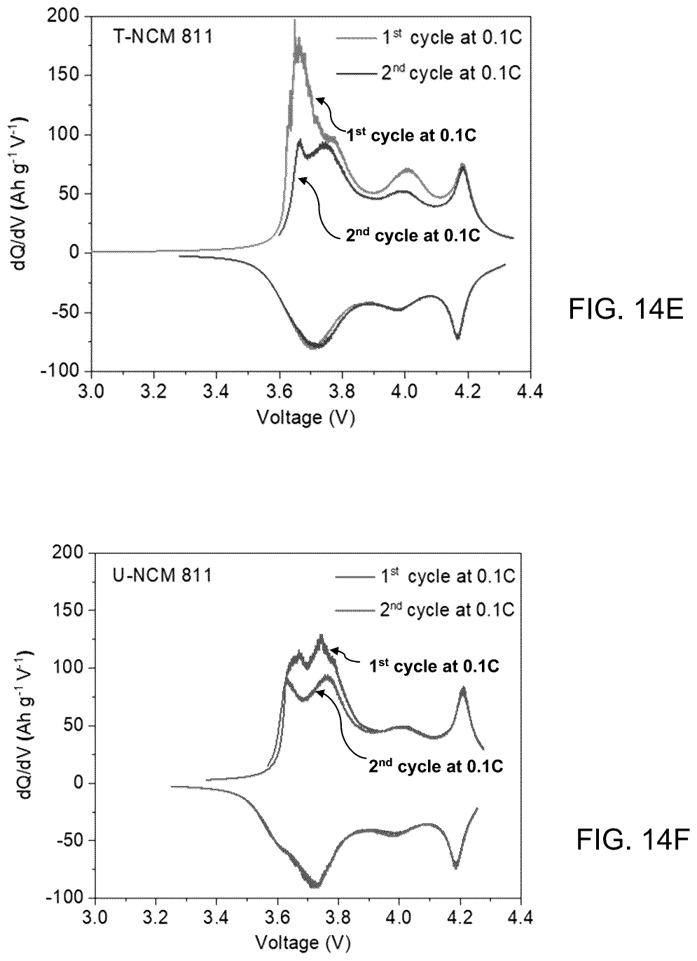

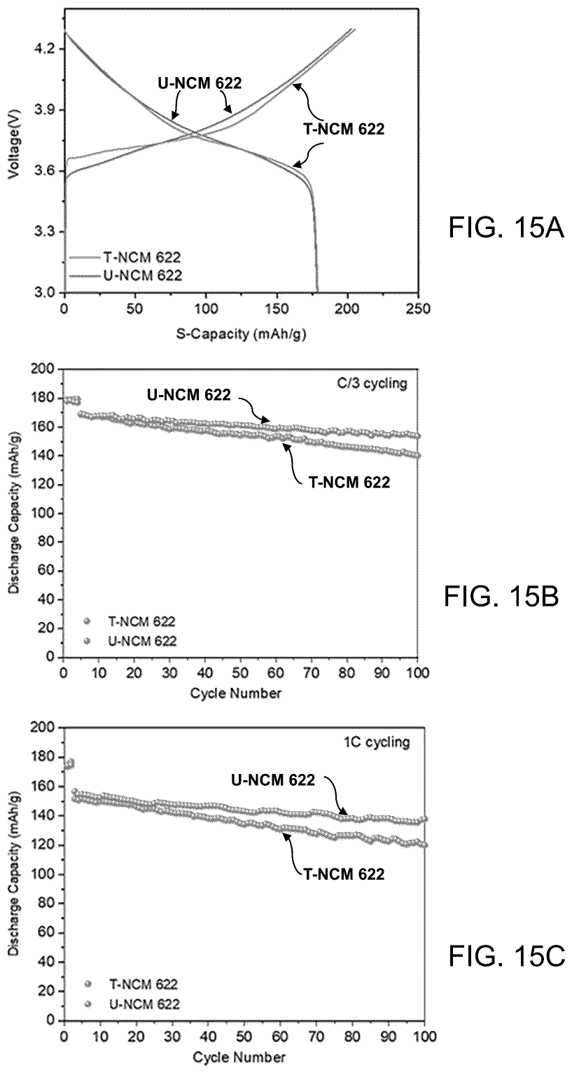

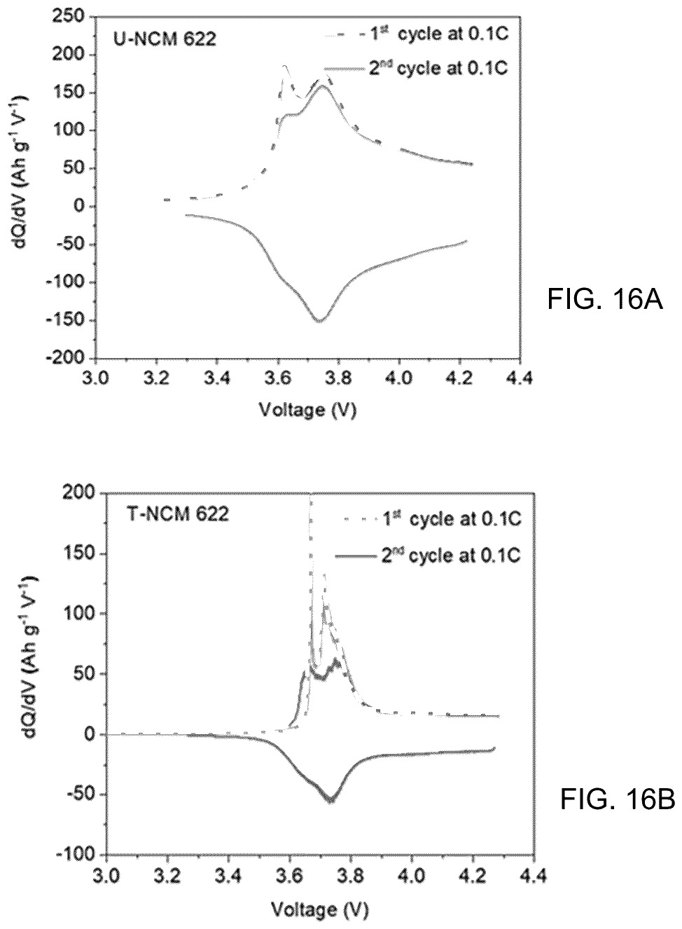

The U-NCM 811 exhibited a similar specific discharge capacity at 1^{st} C/10 cycle (˜198 mAh/g) and similar retention under C/3 cycling (FIGS. 14A-C) compared with the pristine sample. Moreover, FIG. 14B illustrates the good rate performance of U-NCM 811 compared with control sample. The 1 C/1 C cycling data revealed the significant improvement of structural durability in upcycled NCM 811, which may be ascribed to the single-crystal structural integrity. The U-NCM 811 showed 82.6% capacity retention after 100 cycles at 1 C/1 C cycling compared to only 72.2% retention in the pristine polycrystal sample (FIG. 14D). To elaborate the difference between U-NCM 811 and T-NCM 811, the dQ/dV curves of the materials of interests were plotted in FIGS. 14E-14F. As shown, the dQ/dV curve of the first two activation cycles, more irreversible capacity appeared at ˜3.8V in upcycled single-crystal NCM while a significant irreversible capacity was observed at ˜4.1V in the pristine polycrystalline NCM. The extra charging capacity at low state of charge (SOC) may be ascribed to the H1-M-H2 transition behavior in the single-crystal NCM 811, similar to that of LiNiO₂, triggered by the rearrangement of Li/vacancy ordering. Sluggish redox kinetics at low SOC governed by ionic transport at low SOC in single-crystals was also confirmed by a recent study. (See, Ge, M., et al., “Kinetic Limitations in Single-Crystal High-Nickel Cathodes”. Angewandte Chemie International Edition 2021, 60 (32), 17350-17355, incorporated herein by reference.) Generally, the dQ/dV feature could show the H1-M-H2 transition existing in the first activation cycle at a slow rate. The smooth transition between H1 to H2 with M phase significantly reduces the strains and mechanical crack on the grain boundaries raised by the coexistence of H1 and H2 phase. This may be one of the factors that leads to the high stability of upcycled single-crystal particles at a high rate. On the other hand, without significant H1-M-H2 phase transition in lower Ni NCMs such as NCM 622, the difference of rate performance in upcycled NCM 622 and pristine sample was not as significant as that in NCM 811, which was only 88.1% vs 81.0% after 100 cycles at 1 C/1 C (FIG. 15C). Both pristine and upcycled NCM 622 cathodes showed similar dQ/dV at ˜4.1V (FIG. 16), suggesting that this phenomenon would not be observed in lower Ni NCMs.

### Example 7: Effect of Pelletization on Electrochemical Performance

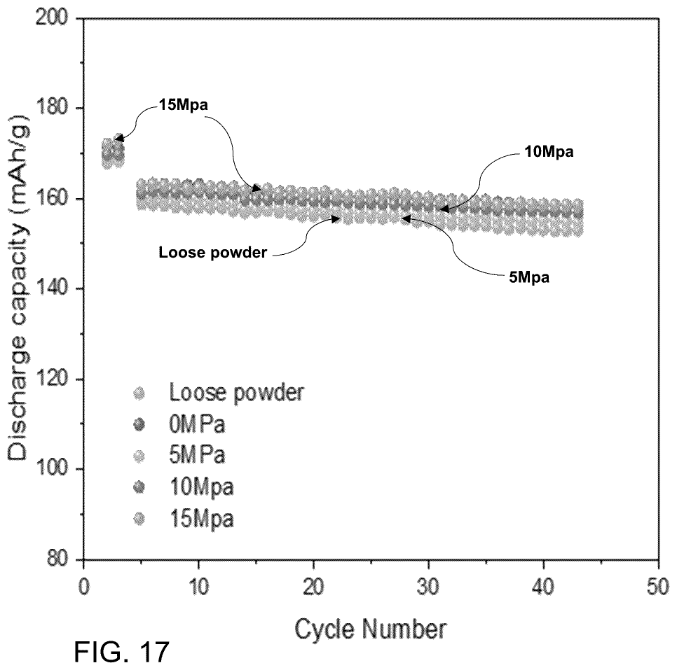

The homogeneous precursor mixture was pelleted with a molar excess of LiOH prior to sintering. Pelletization was determined to be an important factor in improving electrochemical performance as each of the pelleted samples demonstrated improved discharge capacity compared to loose powder (FIG. 17). In addition, higher pressures during pelletization also resulted in improved discharge capacities as pellets produced at an external pressure of 15 MPa, had a higher first discharge capacity and greater capacity retention after 100 cycles compared to pellets produced at lower pressures.

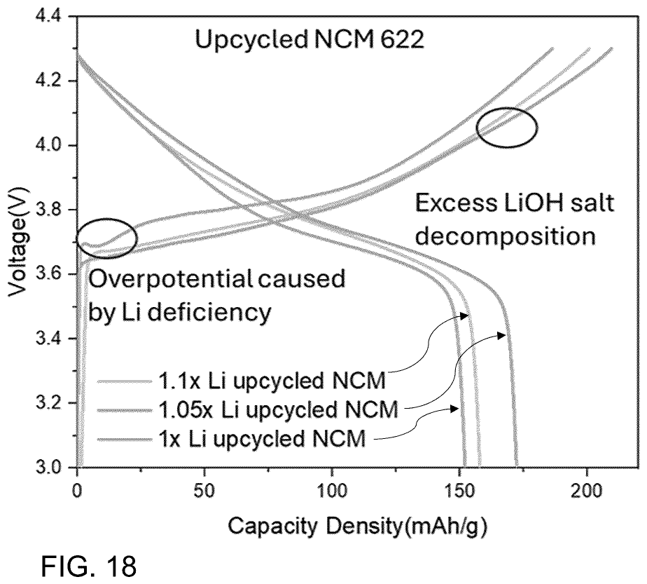

The electrochemical performance of upcycled NCM 622 that was pelleted with varying ratios of LiOH prior to sintering was measured. As seen from the plots of the negative electrode voltage profiles in FIG. 18, lithium deficiencies caused by lithium loss during sintering can increase the overpotential. Pelleting NCM primary particles with a 5% or 10% excess of LiOH resulted in reduced overpotentials. In addition, as can be seen from the positive electrode voltage profile, using a 5% excess of LiOH resulted in the highest capacity density.

The methods described herein provide for direct upcycling cathodes with minimized lithium source. The inventive approach involves converting spent polycrystalline NCM 111 into single-crystal high Ni NCM particles with desired Ni content and crystal size. The approach includes mechanisms for controlling the growth of NCM single-crystals, the effectiveness of which has been demonstrated via evaluation of the size distribution and improved Ni content in the upcycled single-crystal NCM. By leveraging this straightforward process, the desired composition and high phase purity can be achieved in the upcycled single-crystal particles, leading to good rate performance and improved cycling stability compared to the virgin polycrystalline cathodes. Based on the procedures and examples disclosed herein, it will be apparent to those in the art that this cost-effective and scalable upcycling approach for spent LIB materials can be adapted to a wide range of diverse chemistries used in today's NCM cells.

1. A method for direct upcycling of lithium-ion battery cathodes, the method comprising:
providing delithiated NCM particles from spent lithium-ion battery cathodes;
admixing the delithiated NCM particles with a Ni-containing precursor to produce NCM single-crystal particles;
admixing the NCM single-crystal particles with a supplementary lithium source to form a mixture, wherein the supplementary lithium source comprises a single lithium salt; and
treating the mixture to produce single-crystal NCM particles with increased nickel content.

2. The method of claim 1, further comprising relithiating and purifying the delithiated NCM particles prior to admixing with the Ni-containing precursor.

3. The method of claim 1, wherein the single-crystal NCM particles have a nickel content of at least 60%.

4. The method of claim 1, wherein a source of the delithiated NCM particles is D-NCM 111.

5. The method of claim 1, wherein the delithiated NCM particles are ball milled with the Ni-containing precursor to produce NCM single-crystal particles.

6. The method of claim 5, wherein the Ni-containing precursor comprises Ni(OH)₂.

7. The method of claim 1, wherein treating comprises:
pelletizing the mixture to produce a pellet; and
sintering the pellet to produce pelletized single-crystal NCM particles.

8. The method of claim 7, wherein the reaction mixture is pelletized at a pressure of at least about 5 MPa.

9. The method of claim 7, wherein the mixture is pelletized at a pressure of at least about 15 MPa.

10. The method of claim 7, wherein the pellet is sintered at a temperature of between about 850° C. and about 950° C.

11. The method of claim 10, wherein the pellet is sintered at about 850° C.

12. The method of claim 10, wherein a ramping rate during sintering is about 10° C./min.

13. The method of claim 10, wherein the pellet is sintered under pure oxygen.

14. The method of claim 10, wherein the pellet is sintered for at least about 10 h.

15. The method of claim 14, wherein the pellet is sintered for between about 10 h and about 15 h.

16. The method of claim 15, wherein the pellet is sintered for about 12 h.

17. The method of claim 10, wherein, during sintering, the pellet is held at about 480° C. for about 3 h.

18. The method of claim 17, wherein a ramping rate during sintering is about 5° C./min.

19. The method of claim 1, wherein mixture comprises a molar excess of the lithium salt.

20. The method of claim 19, wherein the mixture comprises at least about a 5% molar excess of the lithium salt.

21. The method of claim 19, wherein the mixture comprises at least about a 10% molar excess of the lithium salt.

22. The method of claim 19, wherein the mixture comprises about a 5% molar excess of the lithium salt.

23. The method of claim 1, wherein the lithium salt is LiOH.

24. The method of claim 1, wherein the single-crystal NCM particles comprise NCM 811, having a formula of approximately LiNi_{0.8}Co_{0.1}Mn_{0.1}O₂.

25. The method of claim 24, wherein the NCM 811 particles have a surface area of approximately 1.74 m²/g.

26. The method of claim 1, wherein the single crystal NCM particles comprise NCM 622, having a formula of approximately LiNi_{0.6}Co_{0.2}Mn_{0.2}O₂, or NCM 433, having a formula of approximately LiNi_{0.4}Co_{0.3}Mn_{0.3}O₂.

27. The method of claim 1, wherein the single-crystal NCM particles have an average particle size (D₅₀) of about 1.0 μm to about 5.0 μm.

28. The method of claim 27, wherein the average particle size (D₅₀) is about 1.6 μm to about 2.5 μm.

29. The method of claim 28, wherein the average particle size (D₅₀) is about 1.8 μm.

30. The method of claim 1, wherein an XPS I(003)/I(104) peak intensity ratio of the NCM particles is greater than 1.6.
